(19) United States
(12) Patent Application Publication
(10) Pub. No.: US 2002/0015898 A1
(43) Pub. Date: Feb. 7, 2002

(54) Method of forming identifying elements for mask read only memory

(75) Inventors: Kuan-Chou Sung, Taoyuan Hsien (TW); Chih-Ta Teng, Taipei Hsien (TW); Kuo-Chung Wu, Hsinchu (TW)

Correspondence Address: DARBY & DARBY P.C., 805 Third Avenue, New York, NY, 10022, US

(73) Assignee: Mosel Vitelic Inc.

(21) Appl. No.: 09/782,628

(22) Filed: Feb. 13, 2001

(30) Foreign Application Priority Data
Jun. 28, 2000 (TW) 89112707

(51) Int. Cl. H01L 21/311; H01L 21/4763; H01L 21/3205; G03F 9/00; H01L 21/336; H01L 21/8234; G03C 5/00

(52) U.S. Cl. 430/5; 430/311; 430/313; 438/400; 438/269; 438/275; 438/587; 438/702

(57) ABSTRACT

A method for producing identifying elements for identifying the specification of a MASK ROM, which can easily accompany the standard process of MASK ROM. Also disclosed a method for identifying a MASK ROM, which can identify the code specification of the MASK ROM produced using simple electrical tests before the product is delivered, thereby achieving high efficiency and low error rate.

### BACKGROUND OF THE INVENTION

1. Field of the Invention

The present invention relates to an element-identifying design. More particularly, it relates to a method of forming identifying elements for mask read only memory.

2. Description of the Prior Art

In general, after receiving a customer's order for a mask read only memory (hereinafter referred to as a MASK ROM) code mask is fabricated according to the memory code specification required by the customer. The code mask is used in the lithography process. Ion implantation is then used to perform the coding process for a MASK ROM to complete the code specification required by the customer. Subsequently, a general metalization process is performed on the MASK ROM in order to make electrical contact with other elements.

However, after the code mask is removed from MASK ROM produced in the standard process (e.g., after lithography is completed), the memory ID code formed cannot be identified. Thus, one cannot indentify which product the MASK ROM IC belongs to unless the IC fabrication is completed and the IC is tested. In the semiconductor industry, which emphasizes high efficiency and low error rate, this is a problem to be solved.

### SUMMARY OF THE INVENTION

Therefore, an object of the present invention is to provide a method for producing identifying elements for identifying the specification of a MASK ROM, which can easily accompany the standard process of MASK ROM. Another object of the present invention is to provide a method for identifying a MASK ROM, which can identify the code specification of the MASK ROM produced using simple electrical tests before the product is delivered (i.e., after the code mask is removed), thereby achieving high efficiency and low error rate.

The present invention achieves the above-indicated objects by providing a method of forming identifying elements for a MASK ROM, suitable for a semiconductor substrate, comprising the following steps: designing an element-forming area and an element-identifying area in the semiconductor substrate, and forming an identifying element in the element-identifying area while forming the MASK ROM in the element-forming area, wherein the identifying element is a MOS element or a resistor.

To achieve another object of the present invention, the present invention provides a method for identifying a MASK ROM in a semiconductor substrate having an element-forming area and an element identifying area, wherein a MASK ROM is formed in the element-forming area and a MOS element is formed in the element-identifying area, comprising the following steps: measuring the threshold voltage of the MOS element, defining the code of the MOS element; and identifying the specification of the MASK ROM by means of the code.

In defining the code of the MOS element, the threshold voltage of the MOS device is used. If the threshold voltage measured is high, the code is defined as 0. On the other hand, if the threshold voltage measured is low, the code is defined as 1.

To achieve another object of the present invention, a second method for identifying MASK ROM in a semiconductor substrate having an element-forming area and an element-identifying area, wherein a MASK ROM is formed in the element-forming area and a resistor is formed in the element-identifying area, comprising the following steps: measuring the resistance value of the resistor, defining the code of the resistor, and identifying the specification of the MASK ROM by means of the code.

The code defining the resistor is determined by the resistance value of the resistor. If the resistance value measured is high, the code is defined as 1. If the resistance value measured is low, the code is defined as 0.

Note that the element-forming area and the element-identifying area are determined before producing the wafer, and the method of forming identifying elements can be carried out together with the standard MASK ROM manufacturing process. Thus, the complexity of the process is not increased. Furthermore, the threshold voltage of the MOS element or the resistance value of the resistor can be measured by using simple electrical tests to determine whether the ion implantation step was performed in the area, then defining the ID code digitally. Therefore, the code specification of the MASK ROM can be identified.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 shows the flow chart of the first embodiment of the present invention;

FIGS. 2A-2D show the cross-sections of the manufacturing process of the identifying elements in accordance with the first embodiment of the present invention;

FIG. 3 shows the flow chart of the second embodiment of the present invention; and

FIGS. 4A-4C show the cross-sections of the manufacturing process of the identifying elements in accordance with the second embodiment of the present invention.

### DETAILED DESCRIPTION OF THE INVENTION

First Embodiment

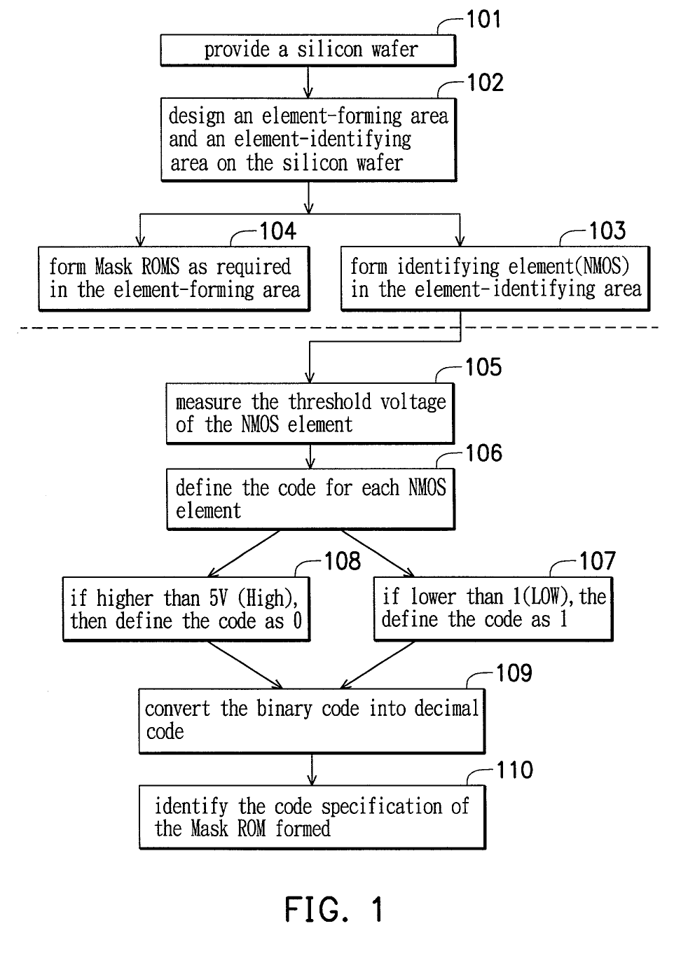

FIG. 1 shows the flow chart of forming the identifying elements for a MASK ROM and the identifying method in accordance with the first embodiment. The first half of the process of this embodiment provides a method for forming the identifying elements of the MASK ROMS. A semiconductor wafer, e.g., silicon wafer, is provided in step 101; next, an element-forming area and an element-identifying area are designed on the silicon wafer in step 102. The element-forming area can be the memory array area for forming the cells of MASK ROM. The element-identifying area can be located in scribe lines, which seperate MASK ROM chips from each other. Therefore, there is no penalty of silicon area loss. Thereafter, two steps are carried out on the silicon wafer simultaneously: forming a plurality of identifying elements (NMOS elements) in the element-identifying area in step 103; forming a plurality of MASK ROMs in the element-forming area in step 104. Note that these two steps are performed by lithography and ion implantation. In comparison with the conventional MASK ROM, the difference only lies in the design of the mask patterns for fabricating the MASK ROM IC, so the identifying elements and MASK ROMs can be produced simultaneously without adding additional manufacturing steps. Therefore, the cost of the manufacturing and complexity are not increased.

Next, the second half of the process of this embodiment is described, i.e., the method of extracting the codes stored in the identifying elements to identify the MASK ROM. After the wafer of the Mask ROM according to the present invention has at least been patterned with a first metal layer for interconnection, the identifying elements in scribe lines can be probed and indentified though the MASK ROMs are not accessible. In order to identify and confirm the specification of the MASK ROM formed, some simple tests need to be performed on the identifying elements (i.e. NMOS elements): step 105, measuring the threshold voltage of the NMOS elements; and step 106, defining the codes of NMOS elements. In detail, step 106 can be divided into step 107 and step 108. In step 107, if the threshold voltage is higher than 5 V, then the code is defined as 0; in step 108, if the threshold voltage is lower than 1 V, then the code is defined as 1. The binary code measured is converted to decimal codes (step 109), and in step 110, the code specifications of the MASK ROMs formed are identified.

For example, if the threshold voltage measured is higher than 5 V, the code is “0”; if the threshold voltage measured is lower than 1 V, the code is “1”. In other words, if the threshold voltage of an NMOS transistor measured is relatively high, the code is “0”. Similarly, if the threshold voltage of a NMOS transistor measured is relatively low, the code is “1”. Therefore, the codes can be identified by using NMOS elements and the level of the threshold voltage measured to identify the program codes of the MASK ROMs produced.

Referring to Table 1, the binary codes and threshold voltages of the cells of MASK ROM with ID code “102” are listed:

TABLE 1

| | | | |
|---|---|---|---|
| Threshold | HHHL | HHHH | HHLH |
| voltage | | | |
| Binary | 0001 | 0000 | 0010 |
| Code | | | |
| Decimal | 1 | 0 | 2 |
| code | | | |

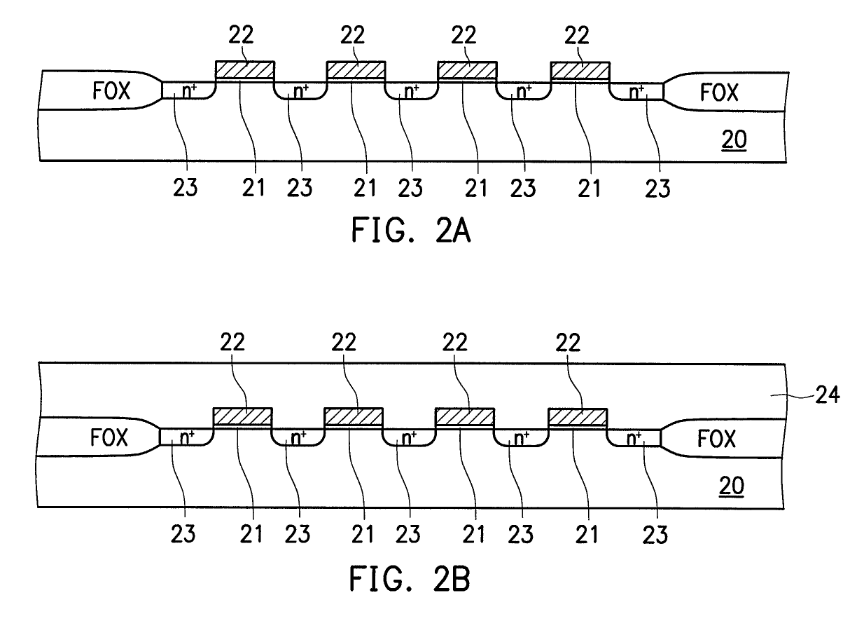

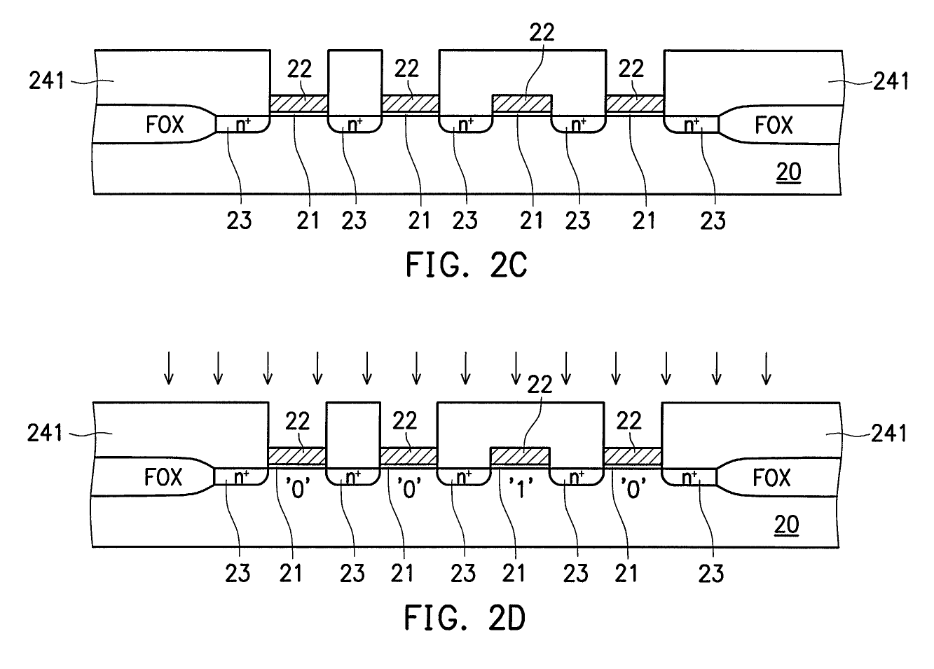

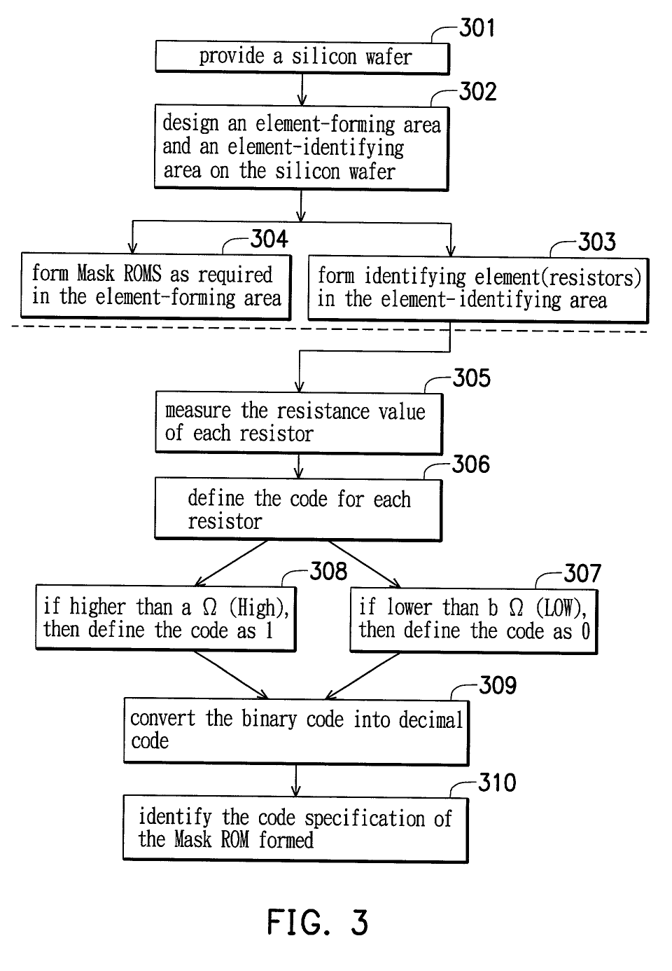

Next, referring to FIGS. 2A-2D, the method of forming identifying elements in the element-identifying area is shown. First, referring to FIG. 2A, a plurality of NMOS elements are formed on a scribe line of a semiconductor substrate. The manufacturing process for the NMOS elements in this embodiment can be the same as that for general MOS, e.g., forming a field oxide (FOX) on the surface of a silicon substrate 20 using LOCOS method to isolate the active area on which electrical elements will be formed, then depositing and defining a gate oxide layer 21 (for example, silicon dioxide layer) and a gate electrode 22 (for example, polysilicon gate electrode) in that area. Subsequently, ions (for example, Phosphoric ions or Arsenic ions) are implanted into the silicon substrate 20 using the gate electrode 22 as a mask to form source/drain 23 in silicon substrate 20 on two sides of the gate electrode 22 nearby.

Next, referring to FIG. 2B and FIG. 2C, a patterned photoresist is formed on the surface of the semiconductor substrate. For example, a photoresist layer 24 is coated on the surface of the silicon substrate 20, as shown in FIG. 2B. Next, referring to FIG. 2C, photolithography is performed on the photoresist layer 24 to form a patterned photoresist layer 241 on the surface of the silicon substrate 20.

Note that the mask (not shown) used in this step to carry out the photolithography is the same code mask as the one for coding the MASK ROMs. The pattern determines whether or not the gate electrodes of the MASK ROMs or the NMOS elements are covered, i.e., whether the subsequent ion implantation step is performed on individual memory cells perform. This determines whether the threshold voltage of each element or each MASK ROM cell is raised higher.

Next, Boron ions are implanted into silicon substrate (i.e. in the channel of the individual transistor) using ion implantation and the patterned photoresist layer 241 as the mask to adjust the threshold voltages of the memory cells. AS shown in FIG. 2D, the code of memory cell implanted with Boron ions is defined as “0”, and the code of memory cell without Boron ion implanted is defined as “1”. Thus the code as shown in FIG. 2D is “0010”, i.e., when converted from a binary number to a decimal number.

Therefore, after the identifying elements of the present invention are set, the threshold voltage of the individual element can be tested by simple electrical tests, thereby determining the corresponding binary number (0 or 1), and then deducing the corresponding decimal number, to identify the code specification of each MASK ROM.

Note that 4 NMOS elements (i.e., 4 bits) are used to represent a decimal number in this embodiment, and a three digit decimal number is used to represent a code specification; however, this is only an example. In application, the number of memory cells can be adjusted as required.

In addition, the photolithography and ion implantation steps described above are performed simultaneously with the photolithography and ion implantation steps of forming the MASK ROM. Therefore, the complexity of the manufacturing process is not increased. After the formation of the above-mentioned elements, a metalization process can be carried out as required (including forming a dielectric layer, contact plug, metal layer etc) so that the NMOS elements can form electrical contact with other elements.

Second Embodiment

Similarly, the concept of the present invention can be achieved by resistors. As in the first embodiment, the first half of the process of the second embodiment provides a method of forming identifying elements for the MASK ROM. In step 301, a semiconductor wafer, for example, silicon wafer, is provided. In step 302, an element-forming area and an element-identifying area are designed in the silicon wafer. The element-identifying area may be located in scribe lines, but does not limited to the scribe lines. The element-forming area can be the memory array of MASK ROM. Then, two steps are performed on the silicon wafer paralled: step 303 a plurality of identifying elements (resistors) are formed in the element-identifying area, and step 304 a plurality of MASK ROM elements are formed as required in the element-forming area.

The following will describe the second half of manufacturing process of this embodiment, i.e., the method of extracting the codes stored in the resistors to identify a MASK ROM. After the wafer of the MASK ROM according to the present invention have at least been patterned with a first metal layer for interconnection, the resistors in scribe lines can be probed and indentified though the MASK ROMs are not accessible. In order to identify and confirm the formed specification of the MASK ROM, some simple tests need to be performed on the identifying elements (i.e., resistors). In step 305, the resistance values of the resistors are measured first. In step 306, the code of each resistor is defined. In detail, this step can be divided into step 307 and 308. In step 307, if the resistance value is higher than a, the code is defined as 1. In step 308, if the resistance value is lower than b, the code is defined as 0 (wherein a>b) . Then, the binary codes measured are converted to decimal codes (step 309), and the code specification of the MASK ROM is identified in step 310.

Therefore, specification codes can be deduced from measuring the resistance values in individual areas. For example, if the resistance value measured in one area is higher than a, the code is defined as 1; if the resistance value measured in the area is lower than b, the code is defined as 0 (wherein a>b).

In other words, if the resistance value measured is relatively high, the code is represented as “1”, if the resistance value measured is relatively low, the code is represented as “0”. Therefore, the resistance values can be used to determine the ID code of the MASK ROM.

Referring to Table 2, it lists the MASK ROM with an ID code “105”, wherein resistance values are used to represent the binary and decimal codes.

TABLE 2

| Resistance | HHHL | HHHH | LHLH |
|---|---|---|---|
| value | | | |
| Binary code | 0001 | 0000 | 0101 |
| Decimal code | 1 | 0 | 5 |

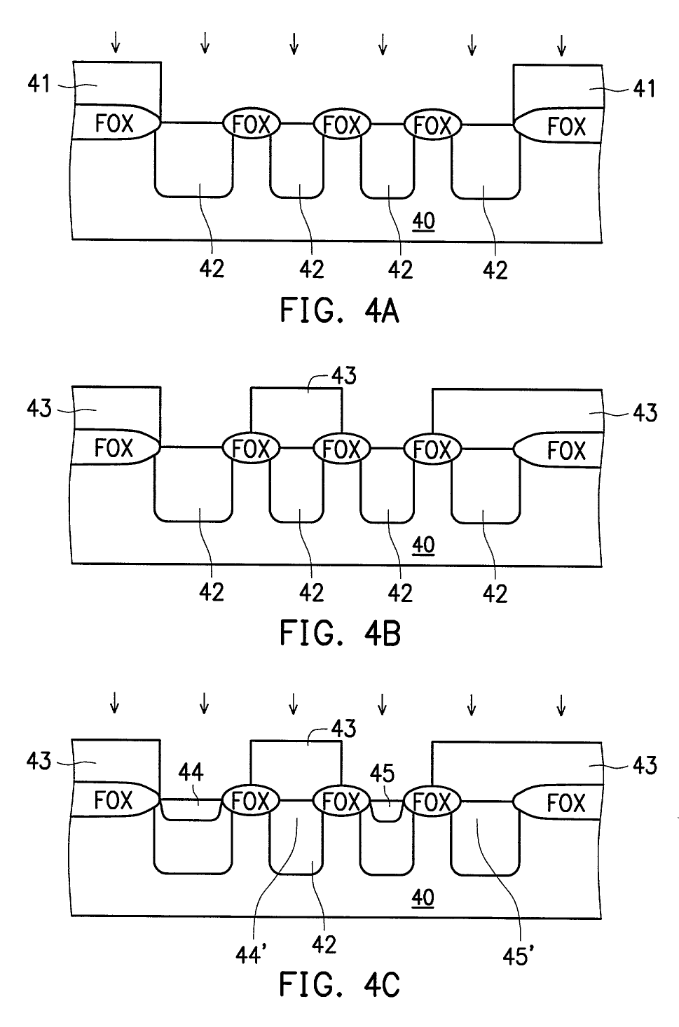

Next, referring to FIGS. 4A-4C, the method of forming an identifying element in the element-identifying area is shown. First, referring to FIG. 4A, a patterned photoresist layer is formed on the surface of the semiconductor substrate. For example, referring to FIG. 4A and 4B, the LOCOS method is used to form field oxides FOXs on the surface of a silicon substrate 40 to isolate the area in which identifying elements are to be formed, then a photoresist layer (not shown) is formed on the surface of the silicon substrate 40, and photolithography is performed on the photoresist layer to form a first patterned photoresist layer 41 on the surface of the silicon substrate 40. Subsequently, ions (for example, Phosphoric ions) are implanted into the silicon substrate 40 not covered by the first patterned photoresist layer 41 to form N-well regions 42, as shown in FIG. 4A. Next, after removing the first patterned photoresist layer 41, a second patterned photoresist layer 43 is formed on the surface of the silicon substrate 40, as shown in FIG. 4B.

Note that the pattern of the mask (not shown) used to perform the photolithography in this step is the major factor determining whether a subsequent ion implantation step will be performed on the well regions 42, i.e. This determines the resistance values of the resistor area.

Next, ions are implanted into the semiconductor substrate using the patterned photoresist as the mask. For example, referring to FIG. 4C, Boron ions are ion-implanted into the N-well region 42 to form areas 44, 45 with smaller resistance values and areas 44′, 45′ with larger resistance values. Therefore, the areas 44, 45 with Boron ions implanted (i.e., areas with smaller resistance values) can be defined as codes “0”, and the areas 44′, 45′ without Boron ions implanted (i.e., areas with larger resistance values) can be defined as codes “1”. Therefore, the binary code as shown in FIG. 4C is “0101”, which becomes “5” when converted into a decimal number.

Also note that 4 resistors (i.e., 4 bits) are used to represent a decimal code in table 2 of this embodiment, and 3 decimal codes are used to represent a code specification. However, this is only one possible example In practice, the number of resistors can be adjusted as required.

The formation of the well resistors, which is compatible to the process of convention MASK ROM process, is well known in the art. As the photolithography and ion implantation steps for writing codes into the identifying element are carried out simultaneously with the photolithography and ion implantation steps for writing codes into the MASK ROM elements, the complexity of the manufacturing process will not increase. After the above-mentioned elements are formed, a metalization process (including forming a dielectric layer, contact plug, metal layer etc) can be carried out as required so that the resistor areas can form electrical contact with other elements.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming identifying elements for a MASK ROM, suitable for a semiconductor substrate, comprising the following steps:
designing an element-forming area and an element-identifying area in the semiconductor substrate; and
forming an identifying element in the element-identifying area while forming the MASK ROM in the element-forming area.

2. The method as claimed in claim 1, wherein the identifying element is a MOS element.

3. The method as claimed in claim 1, wherein the identifying element is a resistor.

4. The method as claimed in claim 2, wherein the method of forming the MOS element further comprises the following steps:
forming a plurality of MOS elements with sources/drains doped with ions of a first type on a semiconductor substrate doped with ions of a second type;
forming a patterned photoresist layer on the surface of the semiconductor substrate; and
using the patterned photoresist layer as a mask, implanting the ions of the second type into the semiconductor substrate to adjust the threshold voltage of the MOS elements.

5. The method as claimed in claim 4, further comprising a step of performing a metalization process so that the memory cells form electrical contact with other elements.

6. The method as claimed in claim 5, wherein the semiconductor substrate is a silicon substrate.

7. The method as claimed in claim 6, wherein the first type is P type, and the second type is N type.

8. The method as claimed in claim 6, wherein the first type is N type, and the second type is P type.

9. The method as claimed in claim 3, wherein the step of forming the resistor further comprises the following steps:
forming a patterned photoresist layer on the surface of the semiconductor substrate; and
using the patterned photoresist layer as a mask, implanting ions of a second type into the semiconductor substrate.

10. The method as claimed in claim 9, further comprising forming a well of a first type in the semiconductor substrate before forming the patterned photoresist layer.

11. The method as claimed in claim 10, wherein the semiconductor substrate is silicon substrate.

12. The method as claimed in claim 11, wherein the first type is P type, and the second type is N type.

13. The method as claimed in claim 11, wherein the first type is N type, and the second type is P type.

14. The method as claimed in claim 1, wherein the identifying element is located in a scribe line.

15. A method of identifying a MASK ROM, suitable for a semiconductor substrate having an element-forming area and an element-identifying area, wherein a MASK ROM is disposed in the element-forming area and a MOS element is disposed in the element-identifying area, comprising the following steps:
measuring the threshold voltage of the MOS element;
defining the code of the MOS element; and
identifying the specification of the mask read only memory formed by way of the code.

16. The identifying method as claimed in claim 15, wherein, if the threshold voltage measured is high, the code is defined as 0, if the threshold voltage measured is low, the code is defined as 1.

17. The identifying method as claimed in claim 15, further comprising the step of converting the binary code into decimal code after the step of defining the code for the MOS element.

18. A method of identifying a mask read only memory, suitable for a semiconductor substrate having an element-forming area and an elements-identifying area, wherein a mask read only memory is disposed in the element-forming area and a resistor is disposed in the element-identifying area, comprising the following steps:
measuring the resistance value of the resistor;
defining the code of the resistor; and
identifying the specification of the mask read only memory formed by way of the code.

19. The identifying method as claimed in claim 18, wherein, if the resistance value measured is high, the code is defined as 1, if the resistance value measured is low, the code is defined as 0.

20. The identifying method as claimed in claim 18, further comprising a step of converting the binary code into decimal code after the step of defining the code for the resistor.
